(19) United States
(12) Patent Application Publication
(10) Pub. No.: US 2009/0068600 A1
(43) Pub. Date: Mar. 12, 2009

(54) METHOD FOR ENHANCING OPTICAL STABILITY OF THREE-DIMENSIONAL MICROMOLDED PRODUCT

(75) Inventors: Takahiro Asai, Kanagawa (JP); Toru Takahashi, Kanagawa (JP)

Correspondence Address: PROCOPIO, CORY, HARGREAVES & SAVITCH LLP, 530 B STREET, SUITE 2100, SAN DIEGO, CA, 92101, US

(73) Assignee: TOKYO OHKA KOGYO CO., LTD., Kawasaki-shi, Kanagawa (JP)

(21) Appl. No.: 11/913,402

(22) PCT Filed: May 11, 2006
(86) PCT No.: PCT/JP2006/309470

§ 371 Date: Nov. 1, 2007

(30) Foreign Application Priority Data
May 12, 2005 (JP) 2005-139913

(51) Int. Cl. G03F 7/20

(52) U.S. Cl. 430/325

(57) ABSTRACT

In order to enhance the optical stability of a three-dimensional micromolded product having optical transparency produced by irradiating a molded layer formed of a photosensitive resin composition provided on a transparent substrate with an actinic radiation from the transparent substrate side so that the quantity of light is varied along the plane of the transparent substrate and dissolving and removing the exposed molded layer in its uncured part with a developing solution, a potassium carbonate solution is used as the developing solution. This constitution can prevent a deterioration in transparency of the transparent three-dimensional micromolded product, incorporated in an optical component, with the elapse of time. That is, the optical stability of the optically transparent three-dimensional micromolded product can be enhanced.

### TECHNICAL FIELD

The present invention relates to a method for enhancing stability of optical characteristics such as transparency of a transparent three-dimensional micro-molded product such as a micro lenses.

### BACKGROUND ART

Recently, the progress of optical components such as liquid crystal display devices, liquid crystal projectors, and optical communication apparatuses is remarkable, so that it has been required to miniaturize the parts. Essential optical elements for an optical system of such optical components include a micro lens, a microlens array, and a transparent, compact, and lightweight three-dimensional micro-molded product such as a transparent panel of a display device, a transparent substrate, and a transparent partition. This three-dimensional micro-molded product is required to be transparent, compact, lightweight, and also have facilitated formability suitable for high-volume production. To meet such requirements, these three-dimensional micro-molded products are produced by using a photosensitive resin composition as a material, forming this photosensitive resin composition to have a constant thickness, conducting pattern exposure in accordance with the objective shape such as lenses on the obtained photosensitive resin layer, and dissolving uncured parts with a developing solution to be removed after exposure (for example, see Patent Documents 1, 2 and 3).

Patent Document 1: Japanese Unexamined Patent Application Publication No. Hei 7-268177

Patent Document 2: Japanese Unexamined Patent Application Publication No. 2002-182388

Patent Document 3: Japanese Unexamined Patent Application Publication No. 2004-334184

### DISCLOSURE OF THE INVENTION

### Problems to be Solved by the Invention

The three-dimensional micro-molded product obtained by using the photosensitive resin composition is built in a optical component and used permanently. For this three-dimensional micro-molded product, it is required that deterioration of optical characteristics does not to occur at earliest until the life of the optical component expires. The required optical characteristics include a predetermined transparency or more, and a constant refractive index. The transparency interrelates with various characteristics such as colorability, haze (cloudiness), and light transmittance, so that the requirements for colorability and light transmittance vary depending on the optical component to be applied, but it is necessary to lower haze as much as possible for any applications.

Haze in a transparent molded product made of resin is initially caused by ununiformity of a resin and flaws on the surface of a molded product; however, it can be avoided by strictly following an operation standard in the course of the production. There is a type of haze in a transparent molded product made of resin which is not recognized in the initial production, but gradually occurs while continuing use of a optical component, and then remarkably deteriorates the optical characteristics of a product. Occurrence frequency of such haze that occurs with time is not that high but cannot be predicted at first and occurs in use of the product, whereby the reliability of the product would be lost remarkably. In view of the circumstances described above, an objective of the present invention is to provide a method for enabling to prevent a transparent three-dimensional micro-molded product built in a optical component from deterioration of the transparency with time, in other words, a method for enhancing the optical stability of the three-dimensional micro-molded product having optical transparency.

### Means for Solving the Problems

As the inventors have conducted extensive experiments and studies to solve the abovementioned problems, they have found the followings.

Accordingly, it was found that haze that occurs in transparent three-dimensional micro-molded product after the production with time is identified as a microcrystalline substance; this microcrystalline substance does not always occur; occurrence frequency is greatly varied by the use environment of the product; and the use environment in which the haze occurs frequently is high-temperature and humidity environment.

When a transparent three-dimensional micro-molded product is placed under a high-temperature and humidity environment for a long period, microcrystalline substances precipitate predominantly on the surface to yield haze that remarkably deteriorates the transparency of the three-dimensional micro-molded product. The causative substance of this crystallized substance was not speculated to be introduced externally during use, but be a component of the material resin or a compound used in production. Therefore, attempts to specify the causative substance were conducted for all materials to be used. As a result, it was revealed unexpectedly to result from a developing solution which develops a resin layer after exposure. Conventionally, an organic compound such as methyl isobutyl ketone has been used as a developing solution for producing a transparent three-dimensional micro-molded product. With these organic compounds, haze does not occur in the molded product even with time as described above. However, these organic compounds have a problem for environmental pollution. Currently, in the production of the transparent three-dimensional micro-molded products, mainly sodium carbonate (Na₂CO₃), and m-silicic acid and TMAH (tetramethylammonium hydroxide) are often used in a developing solution due to little environmental pollution. In case of use of TMAH among these, precipitation of the crystalline substance occurs on the surface of the molded product without exception although the precipitation quantity is comparatively small. It was confirmed that the above-mentioned substances cause precipitation of the crystalline substance because precipitation of the crystalline substance did not occur at all when potassium carbonate (K₂CO₃) was used as a developing solution in place of these substances. It was also confirmed that more precipitation of the crystalline substance resulting from this developing solution is caused on the molded product which was formed by an exposure formation method to form a cured latent image of the three-dimensional micro-molded product on the formed layer by a back face exposure method, namely by exposing from the back face (transparent substrate side) of the formed layer (photopolymer resin layer) on the transparent substrate, as compared with the molded product formed by exposure from the front face side. It is considered that the closer the surface of molded product is exposed by the back face, the less light exposure is attained, whereby the curing is retarded, and that the part on the surface where the curing is retarded shall be brought into contact with a developing solution for a longer period at the time of development.

The present invention was made based on the aforementioned findings. Accordingly, the method for enhancing the optical stability of the three-dimensional micro-molded product having optical transparency according to the present invention, the three-dimensional micro-molded product is obtained by irradiating actinic rays from the transparent substrate side to a formed layer including a photosensitive resin composition provided on a transparent substrate so that light volume varies along the planer direction of the transparent substrate, and dissolving and removing a non-cured part of the formed layer after irradiation with a developing solution, wherein a potassium carbonate solution is used as the developing solution.

### EFFECTS OF THE INVENTION

The method for enhancing the optical stability of the three-dimensional micro-molded product having optical transparency according to the present invention provides optical stability so as not to cause precipitation of crystalline substance which results in haze in the molded product even when a three-dimensional micro-molded product is used under a high-temperature and humidity environment deviated from a normal use environment.

### PREFERRED MODE FOR CARRYING OUT THE INVENTION

In the method for enhancing the optical stability of the three-dimensional micro-molded product having optical transparency according to the present invention, the three-dimensional micro-molded product is obtained by irradiating actinic rays from the transparent substrate side to a formed layer including a photosensitive resin composition provided on a transparent substrate so that light volume varies along the planer direction of the transparent substrate and dissolving and removing a non-cured part of the formed layer after irradiation with a developing solution, wherein a potassium carbonate solution is used as the developing solution.

In the present invention, the optical stability is preferably maintained after the subject three-dimensional micro-molded product is exposed to high-temperature and humidity load. This optical stability is desirably maintained for at least 100 hours even under high-temperature and humidity load at 60° C. and 90RH %.

In the present invention, the optical stability means maintenance of the optical transparency, which means that there is no precipitation of the crystalline substance in the molded product even after the high-temperature and humidity load.

The photosensitive resin composition that is a material constituting the three-dimensional micro-molded product subjected to enhance optical stability in the present invention is described below.

The photosensitive resin composition that is a material constituting the three-dimensional micro-molded product at least includes an alkali-soluble resin (A), a photopolymerizable compound (B), and a photoinitiator (C).

### Alkali-Soluble Resin (A)

Examples of the alkali-soluble resin (A) may include (meth)acryl based resins, styrene based resins, epoxy based resins, amide based resins, amide epoxy based resins, alkyd based resins, phenol based resins, phenol novolak based resins and cresol novolak based resins. The (meth)acryl based resin is preferable in terms of alkaline development property.

As the above (meth)acryl based resins, those obtained by polymerizing or copolymerizing monomers shown below may be used. These monomers may also be included as the component (B) described later. As these monomers, for example, (meth)acrylic ester, ethylenic unsaturated carboxylic acid, and other copolymerizable monomers can be preferably used. Specifically, styrene, benzyl (meth)acrylate, cyclohexyl (meth)acrylate, phenoxyethyl (meth)acrylate, phenoxypolyethylene glycol (meth)acrylate, nonylphenoxypolyethylene glycol mono(meth)acrylate, nonylphenoxypolypropylene mono(meth)acrylate, 2-hydroxy-3-phenoxypropyl acrylate, 2-acryloyloxyethyl phthalate, 2-acryloyloxyethyl-2-hydroxyethyl phthalate, 2-methacryloyloxyethyl-2-hydroxypropyl phthalate, methyl (meth)acrylate, ethyl (meth)acrylate, n-propyl (meth)acrylate, i-propyl (meth)acrylate, n-butyl (meth)acrylate, i-butyl (meth)acrylate, sec-butyl (meth)acrylate, tert-butyl (meth)acrylate, 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, 4-hydroxybutyl (meth)acrylate, 3-ethylhexyl (meth)acrylate, ethylene glycol (meth)acrylate, glycerol (meth)acrylate, dipentaerythritol mono(meth)acrylate, dimethylaminoethyl (meth)acrylate, diethylaminoethyl (meth)acrylate, tetrahydrofurfuryl (meth)acrylate, glycidyl (meth)acrylate, 2,2,2-trifluoroethyl (meth)acrylate, 2,2,3,3-trifluoropropyl (meth)acrylate, (meth)acrylic acid, α-bromo(meth)acrylic acid, β-furyl (meth)acrylic acid, crotonic acid, propiolic acid, cinnamic acid, α-cyanocinnamic acid, maleic acid, maleic anhydride, maleic acid monomethyl, maleic acid monoethyl, maleic acid monoisopropyl, fumaric acid, itaconic acid, itaconic anhydride, citraconic acid, citraconic anhydride, and the like are included. Among them, (meth)acrylic acid, methyl (meth)acrylate and styrene are suitably used.

Other copolymerizable monomers include fumaric acid esters in which the exemplified compound of the above-mentioned (meth)acrylate is substituted with fumarate, maleic acid esters in which the exemplified compound of the above-mentioned (meth)acrylate is substituted with maleate, crotonic acid esters in which the exemplified compound of the above-mentioned (meth)acrylate is substituted with crotonate, itaconic acid esters in which the exemplified compound of the above-mentioned (meth)acrylate is substituted with itaconate, α-methyl styrene, o-vinyltoluene, m-vinyltoluene, p-vinyltoluene, o-chlorostyrene, m-chlorostyrene, p-chlorostyrene, o-methoxystyrene, m-methoxystyrene, p-methoxystyrene, vinyl acetate, vinyl butyrate, vinyl propionate, (meth)acrylamide, (meth)acrylonitrile, isoprene, chloroprene, 3-butadiene, vinyl-n-butyl ether, and the like.

In addition to the polymers/copolymers of the above monomers, it is possible to use cellulose derivatives such as cellulose, hydroxymethylcellulose, hydroxyethylcellulose, hydroxypropylcellulose, carboxymethylcellulose, carboxyethylcellulose and carboxyethylmethylcellulose, and additionally copolymers of these cellulose derivatives with the ethylenic unsaturated carboxylic acid or the (meth)acrylate compound. Furthermore, polyvinyl alcohols such as a polybutyral resin which is a reaction product of polyvinyl alcohol and butylaldehyde, polyesters obtained by ring-opening and polymerizing lactones such as δ-valerolactone, ε-caprolactone, β-propiolactone, α-methyl-β-propiolactone, β-methyl-β-propiolactone, α-methyl-β-propiolactone, β-methyl-β-propiolactone, α,α-dimethyl-β-propiolactone and β,β-dimethyl-β-propiolactone, polyesters obtained by condensation reactions of diols of one or more alkylene glycols such as ethylene glycol, propylene glycol, diethylene glycol, triethylene glycol, dipropylene glycol and neopentyl glycol with dicarboxylic acids such as maleic acid, fumaric acid, glutaric acid and adipic acid, polyethers such as polyethylene glycol, polypropylene glycol, polytetramethylene glycol and polypentamethylene glycol, polycarbonates which are reaction products of diols such as bisphenol A, hydroquinone and dihydroxycyclohexane with carbonyl compounds such as diphenyl carbonate, phosgene and succinic anhydride may be included. The above component (A) may be used alone or in combination of two or more.

The alkali-soluble resin (A) preferably contains a carboxyl group in terms of alkaline development property. Such a component (A) may be produced by performing radical polymerization of a monomer having the carboxyl group with another monomer. In this case, it is preferable to include (meth)acrylic acid.

### Photopolymerizable Compound (B)

The photopolymerizable compound (B) has at least one polymerizable ethylenic unsaturated group in a molecule. This photopolymerizable compound (B) preferably contains a compound (B-1) obtained by reacting α,β-unsaturated carboxylic acid with polyhydric alcohol. By containing the compound (B-1), the sensitivity is increased. Examples of the above α,β-unsaturated carboxylic acid may suitably include, but are not limited to, (meth)acrylic acid.

Examples of the above compound (B-1) obtained by reacting α,β-unsaturated carboxylic acid with polyhydric alcohol may include polyalkylene glycol di(meth)acrylate, ethylene glycol di(meth)acrylate, propylene glycol di(meth)acrylate, polyethylene polytrimethylolpropane di(meth)acrylate, trimethylolpropane tri(meth)acrylate, trimethylolpropane ethoxy tri(meth)acrylate, trimethylolpropane diethoxy tri(meth)acrylate, trimethylolpropane triethoxy tri(meth)acrylate, trimethylolpropane tetraethoxy tri(meth)acrylate, trimethylolpropane pentaethoxy tri(meth)acrylate, tetramethylolmethane tri(meth)acrylate, tetramethylolmethane tetra(meth)acrylate, tetramethylolpropane tetra(meth)acrylate, pentaerythritol tri(meth)acrylate, pentaerythritol tetra(meth)acrylate, pentaerythritol penta(meth)acrylate, dipentaerythritol penta(meth)acrylate, dipentaerythritol hexa(meth)acrylate, and the like. These compounds may be used alone or in combination of two or more.

Examples of the above polyalkylene glycol di(meth)acrylate may include polyethylene glycol di(meth)acrylate, polypropylene glycol di(meth)acrylate, polyethylenepolypropylene glycol di(meth)acrylate, and the like. Among them, polyalkylene glycol di(meth)acrylate whose molecular weight is in the range of 500 to 2,000 is suitably used because the tent strength is enhanced. A specific suitable example may include ethoxylated polypropylene glycol diacrylate.

The amount of the above compound (B-1) to be combined is preferably 30 to 100 parts by weight, and more preferably 50 to 90 parts by weight based on 100 parts by weight of the alkali-soluble resin (A) solid content.

The photopolymerizable compound (B) may further contain a compound (B-2) having a bisphenol skeleton. By containing this compound (B-2), the stability for light and heat is enhanced.

Examples of the above compound (B-2) having the bisphenol skeleton may include bisphenol A type compounds, bisphenol F type compounds and bisphenol S type compounds. In the present invention, 2,2-bis[4-{(meth)acryloxypolyethoxy}phenyl]propane is preferably included in the bisphenol A type compounds. Specific examples may include, but are not limited to, 2,2-bis[4-{(meth)acryloxydiethoxy}phenyl]propane, 2,2-bis[4-{(meth)acryloxytriethoxy}phenyl]propane, 2,2-bis[4-{(meth)acryloxypentaethoxy}phenyl]propane, 2,2-bis[4-{(meth)acryloxydecaethoxy}phenyl]propane, and the like. These compounds may be used alone or in combination of two or more. 2,2-Bis[4-(methacryloxypentaethoxy)phenyl]propane is commercially available as “BPE-500” (Shin-Nakamura Chemical Co., Ltd.), and suitably used.

The amount of the above compound (B-2) to be combined is preferably 30 to 100 parts by weight, and more preferably 50 to 90 parts by weight based on 100 parts by weight of the alkali-soluble resin (A) solid content.

The photopolymerizable compound (B) may contain 2-phenoxy-2-hydroxypropyl (meth)acrylate, 2-(meth)acroyloxy-2-hydroxypropyl phthalate, 2-(meth)acroyloxyethyl-2-hydroxyethyl phthalate, compounds obtained by reacting α,β-unsaturated carboxylic acid with glycidyl group-containing compounds, urethane monomers, nonylphenyldioxylene (meth)acrylate, γ-chloro-β-hydroxypropyl-β′-(meth)acryloyloxyethyl-o-phthalate, β-hydroxyethyl-β′-(meth)acryloyloxyethyl-o-phthalate, β-hydroxypropyl-β′-(meth)acryloyloxyethyl-o-phthalate, and (meth)acrylic acid alkyl ester. Additionally, the monomers exemplified as being capable of combining in the above component (A) may be contained.

Examples of the above glycidyl group-containing compounds may include, but are not limited to, triglycerol di(meth)acrylate.

Examples of the aforementioned urethane monomer may include addition reaction products of (meth)acryl monomer having an OH group at position β with isophorone diisocyanate, 2,6-toluene diisccyanate, 2,4-toluene diisocyanate or 1,6-hexamethylene diisocyanate, tris[(meth)acryloxy tetraethylene glycol isocyanate]hexamethylene isocyanurate, EO-modified urethane di(meth)acrylate, EO- and PO-modified urethane di(meth)acrylate, and the like.

Examples of the above (meth)acrylic acid alkyl ester may include (meth)acrylic acid methyl ester, (meth)acrylic acid ethyl ester, (meth)acrylic acid butyl ester, (meth)acrylic acid 2-ethylhexyl ester, and the like.

The amount of this component (B) (solid content) to be combined is preferably 20 to 60 parts by weight based on 100 parts by weight of a total amount of this component (B) and the component (A). When the amount of the component (B) is too small, the sensitivity is reduced whereas when it is too large, a film forming property is inferior.

### Photoinitiator (C)

The photoinitiator (C) is characterized by including at least a hexaarylbisimidazole based compound (C1) and a multifunctional thiol compound (C2) as essential components. By having the hexaarylbisimidazole based compound (C1), particularly, beneficial effects on adhesion and resolution may be exhibited.

The hexaarylbisimidazole based compound (C1) means a dimer compound of imidazole in which all hydrogen atoms bound to three carbon atoms of an imidazole ring are substituted with aryl groups (including substituted or unsubstituted groups). Specifically, 2-(o-chlorophenyl)-4,5-diphenylimidazole dimer, 2-(o-chlorophenyl)-4,5-di(methoxyphenyl)imidazole dimer, 2-(o-fluorophenyl)-4,5-diphenylimidazole dimer, 2-(o-methoxyphenyl)-4,5-diphenylimidazole dimer, 2-(p-methoxyphenyl)-4,5-diphenylimidazole dimer, 2,4,5-triaryl imidazole dimer such as 2,4,5-triaryl imidazole dimer, 2,2-bis(2,6-dichlorophenyl)-4,5-diphenylimidazole dimer, 2,2′-bis(o-chlorophenyl)-4,4′,5,5′-tetra(p-fluorophenyl)biimidazole, 2,2′-bis(o-bromophenyl)-4,4′,5,5′-tetra(p-iodophenyl)biimidazole, 2,2′-bis(o-chlorophenyl)-4,4′,5,5′-tetra(p-chloronaphthyl)biimidazole, 2,2′-bis(o-chlorophenyl)-4,4′,5,5′-tetra(p-chlorophenyl)biimidazole, 2,2′-bis(o-bromophenyl)-4,4′,5,5′-tetra(p-chloro-p-methoxyphenyl)biimidazole, 2,2′-bis(o-chlorophenyl)-4,4′,5,5′-tetra (o,p-dichlorophenyl)biimidazole, 2,2′-bis(o-chlorophenyl)-4,4′,5,5′-tetra(o,p-dibromophenyl)biimidazole, 2,2′-bis(o-bromophenyl)-4,4′,5,5′-tetra(o,p-dichlorophenyl)biimidazole, 2,2′-bis(o,p-dichlorophenyl)-4,4′,5,5′-tetra(o,p-dichlorophenyl)biimidazole, and the like are included. Among them, the 2-(o-chlorophenyl)-4,5-diphenylimidazole dimer is preferably used.

The multifunctional thiol compound (C2) is a compound having two or more thiol groups in a molecule, and particularly, an aliphatic multifunctional thiol compound having multiple thiol groups in an aliphatic group is preferable. Among them, the thiol compound having a large molecular weight and low vapor pressure is preferable.

Examples of the aliphatic multifunctional thiol compound may include hexanedithiol, decanedithiol, 1,4-dimethylmercaptobenzene, butanediol bisthiopropionate, butanediol bisthioglycolate, ethylene glycol bisthioglycolate, trimethylolpropane tris thioglycolate, butanediol bisthiopropionate, trimethylolpropane tris thiopropionate, trimethylolpropane tris thioglycolate, pentaerythritol tetrakis thiopropionate, pentaerythritol tetrakis thioglycolate, tris hydroxyethyl tris thiopropionate, and additionally thioglycolate and thiopropionate of these polyvalent hydroxy compounds. Among them, trimethylolpropane tristhiopropionate and pentaerythritol tetrakisthioglycolate are suitably used. The photoinitiator (C) may drastically enhance the sensitivity by containing the multifunctional thiol compound (C2) without impairing resolution and causing surface deterioration in the development.

The amount of the above photoinitiator (C) to be combined in the composition is 0.1 to 30 parts by weight based on 100 parts by weight of the alkali-soluble resin (A) solid content. When the amount is less than 0.1 parts by weight, the sensitivity is reduced and practicability is poor. In contrast, when it exceeds 30 parts by weight, the adhesion is reduced. The amount of the essential component (C2) to be combined is 0.1 to 30 parts by weight, preferably 1 to 20 parts by weight and more preferably 1 to 10 parts by weight based on 100 parts by weight of the essential component (C1). When the amount of the essential component (C2) is less than 0.1 parts by weight, the sensitivity is too low whereas when it exceeds 30 parts by weight, the resolution and storage stability with time are deteriorated.

It is preferable that the photosensitive resin composition further contains n-phenylglycine as the photoinitiator (C), because the sensitivity is enhanced by containing n-phenylglycine.

When the photoinitiator (C) contains n-phenylglycine, the amount of n-phenylglycine to be combined is preferably 3 to 20 parts by weight and more preferably 5 to 15 parts by weight based on 100 parts by weight of the essential component (C1). When the amount is less than 3 parts by weight, no effect of enhancing sensitivity is likely to be observed whereas when it exceeds 20 parts by weight, the resolution and the storage stability with time are deteriorated.

The photosensitive resin composition may include an additional photoinitiator other than one described above as far as characteristics required for the three-dimensional micro-molded product obtained after formation are not deteriorated. Examples of such a photoinitiator may include aromatic ketone such as benzophenone, N,N′-tetramethyl-4,4′-diaminobenzophenone, N,N′-tetraethyl-4,4′-diaminobenzophenone, 4-methoxy-4′-dimethylaminobenzophenone, and 2-benzyl-2-dimethylamino-1-(4-morpholinophenyl)-butanone-1,2-methyl-1-[4-(methylthio)phenyl]-2-morpholino-propanone-1; quinones such as 2-ethylanthraquinone, phenanthrenequinone, 2-tert-butylanthraquinone, octamethylanthraquinone, 1,2-benzanthraquinone, 2,3-benzanthraquinone, 2-phenylanthraquinone, 2,3-diphenylanthraquinone, 1-chloroanthraquinone, 2-methylanthraquinone, 1,4-naphthoquinone, 9,10-phenanthraquinone, 2-methyl-1,4-naphthoquinone and 2,3-dimethylanthraquinone; benzoin ether compounds such as benzoin methyl ether, benzoin ethyl ether and benzoin phenyl ether; benzoin compounds such as benzoin, methylbenzoin and ethylbenzoin; benzyl derivatives such as benzylmethylketal; acridine derivatives such as 9-phenylacridine and 1,7-bis(9,9′-acridinyl)heptane, and coumarin based compounds.

### Other Components

In the photosensitive resin composition, organic solvents for dilution of such as alcohols, ketones, acetic acid esters, glycol ethers, glycol ether esters, and petroleum based solvents may be appropriately added if necessary for the purpose of adjusting a viscosity in addition to the above components.

Organic solvents for dilution include, for example, hexane, heptane, octane, nonane, decane, benzene, toluene, xylene, benzyl alcohol, methyl ethyl ketone, acetone, methyl isobutyl ketone, cyclohexanone, methanol, ethanol, propanol, butanol, hexanol, cyclohexanol, ethylene glycol, diethylene glycol, glycerin, ethylene glycol monomethyl ether, ethylene glycol monoethyl ether, propylene glycol monomethyl ether, propylene glycol monomethyl ether, diethylene glycol monomethyl ether, diethylene glycol monoethyl ether, diethylene glycol dimethyl ether, diethylene glycol diethyl ether, 2-methoxybutyl acetate, 3-methoxybutyl acetate, 4-methoxybutyl acetate, 2-methyl-3-methoxybutyl acetate, 3-methyl-3-methoxybutyl acetate, 3-ethyl-3-methoxybutyl acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, methyl lactate, ethyl lactate, methyl acetate, ethyl acetate, propyl acetate, butyl acetate, propylene glycol monomethyl ether, propylene glycol monomethyl ether acetate, methyl propionate, ethyl propionate, methyl benzoate, ethyl benzoate, propyl benzoate, butyl benzoate, methyl butyrate, ethyl butyrate, propyl butyrate, and additionally petroleum based solvents available under trade names such as “Swasol” (Maruzen Petrochemical Co., Ltd.) and “Solvesso” (Tonen Petrochemical Co., Ltd.), but are not limited thereto.

Other additives such as adhesion imparting agents, plasticizers, antioxidants, heat polymerization inhibitors, surface tension modifiers, stabilizers, chain transfer agents, anti-foaming agents and flame retardants may also be added appropriately. When the antioxidant is added, the stability for light and heat is likely to be enhanced.

The most preferable combination of the above alkali-soluble resin (A), the photopolymerizable compound (B) and the photoinitiator (C) as the photosensitive resin component of the present invention is obtained by combining 100 parts by weight (in terms of solid content) of a resin with a weight-average molecular weight of 80,000 obtained by copolymerizing methyl methacrylate, methacrylic acid and styrene at a weight ratio of 50:25:25 as the component (A), 40 parts by weight of polyalkylene (C2-4) glycol dimethacrylate (B-1), and 40 parts by weight of 2,2-bis[4-(methacryloxy polyethoxy)phenyl]propane as the component (B), and 10 parts by weight of 2,2′-bis(2-chlorophenyl)-4,4′,5,5′-tetraphenyl-1,2′-biimidazole and 0.2 parts by weight of trimethylol propane tristhiopropionate (TMMP) as the component (C). This combination is entirely excellent in all terms of sensitivity, stability, tent strength, resolution and plating non-staining.

The combination of the above e alkaline-1-soluble resin (A), the photopolymerizable compound (B) and the photoinitiator (C) preferred in light of use in practical production is obtained by combining the (meth)acryl based resin as the component (A), ethoxylated polypropylene glycol dimethacrylate as the component (B), and 2,2′-bis(2-chlorophenyl)-4,4′,5,5′-tetraphenyl-1,2′-biimidazole and trimethylol propane tristhiopropionate (TMMP) as the component (C). This combination is well-balanced in production cost and effects.

For forming an optically transparent three-dimensional micro-molded product using the photosensitive resin composition including the above-mentioned components, the photosensitive resin composition layer may be formed by directly applying this photosensitive resin composition on a transparent substrate, whereby pattern exposure may be conducted in this photosensitive resin composition layer. However, when efficiency and stability of the production is considered, it is desirable that the photosensitive dry film is made once from this photosensitive resin composition, and then this dry film is attached on the transparent substrate, whereby the photosensitive resin composition layer is constituted. The photosensitive dry film will be described below.

The photosensitive dry film is obtained by at least providing the photosensitive resin layer formed from the aforementioned photosensitive resin composition on a support film. When used, the photosensitive resin layer may be provided easily on a material to be treated (substrate) by lapping the revealing photosensitive resin layer over the material to be treated (substrate) and subsequently peeling the support film from the photosensitive resin layer.

By the use of the photosensitive dry film, the layer having more excellent film thickness uniformity and surface smoothness can be formed as compared with the case of forming the photosensitive resin layer by directly applying the photosensitive resin composition on the substrate.

The support film used for producing the photosensitive dry film is not particularly limited as long as the photosensitive resin layer formed as a film on the support film can be peeled easily from the support film, which is a mould releasing film capable of transferring the layer onto the surface of the substrate to be treated of glass, and the like. Examples of such a support film may include flexible films composed of films of synthetic resins such as polyethylene terephthalate, polyethylene, polypropylene, polycarbonate and poly vinyl chloride with a film thickness of 15 to 125 μm. It is preferable that a mould releasing treatment is given to the above support film if necessary to facilitate the transfer.

When the photosensitive resin layer is formed on the support film, the photosensitive resin composition is prepared and the photosensitive resin composition is applied on the support film so that the dried film thickness is 10 to 100 μm using an applicator, a bar coater, a wire bar coater, a roll coater, a curtain flow coater or the like. In particular, the roll coater is preferable because the film thickness uniformity is excellent and the thick film can be formed efficiently.

When the photosensitive resin layer is formed, the photosensitive resin composition may be directly applied on the support film, or a water-soluble resin layer has been previously formed on the support film and the photosensitive resin composition may also be applied on this water-soluble resin layer to form the photosensitive resin layer. The water-soluble resin layer herein prevents tacky adhesion of a mask (pattern) attached firmly upon the exposure as well as an oxygen desensitizing effect of the photosensitive resin. The water-soluble resin layer is formed by applying and drying an aqueous solution of 5 to 20% by weight of a water-soluble polymer such as polyvinyl alcohol or partially saponified polyvinyl acetate so that a dried film thickness is 1 to 10 μm using the bar coater, the roll coater, the curtain flow coater or the like. It is preferable to add ethylene glycol, propylene glycol or polyethylene glycol into the above aqueous solution of the water-soluble polymer when this water-soluble resin layer is formed because the flexibility of the water-soluble resin layer is increased and the mould releasing property from the flexible film is enhanced.

When the thickness of the above water-soluble resin layer is less than 1 μm, poor exposure because of oxygen desensitization occurs in some cases whereas when it exceeds 10 μm, the resolution is likely to be deteriorated. When the above aqueous solution is prepared, taking into consideration a viscosity of the solution and defoamation, a solvent such as methanol, ethylene glycol monomethyl ether or acetone, or a commercially available anti-foaming agent may be added.

In the photosensitive dry film, a protective film may be further provided on the photosensitive resin layer. Protection by the protective film makes storage, transport and handling easy. The photosensitive dry film protected by the protective film may be previously produced and stored for a predetermined period although there is an expiration date for use. Thus, in case of production of the optically transparent three-dimensional micro-molded product, which can be used immediately, the molded product forming process can be streamlined. As this protective film, polyethylene terephthalate film, polypropylene film and polyethylene film with a thickness of about 15 to 125 μm to which silicone has been coated or burned in are suitable.

To make the three-dimensional micro-molded product using this photosensitive dry film, the protective film is first peeled off from the photosensitive dry film, the exposed photopolymer resin layer side is overlapped on the transparent substrate (e.g., glass substrate), and then the photosensitive dry film is adhered on the substrate. When adhered, typically a thermal compression mode in which the substrate has been previously heated and the photosensitive dry film placed thereon is pressed is employed.

Then, the photosensitive resin layer is selectively exposed by exposing the photosensitive resin layer having a laminated support film through the mask or exposing with lithography directly. Specifically, ultraviolet light is irradiated using a low pressure mercury lamp, a high pressure mercury lamp, an ultra high pressure mercury lamp, an arc lamp, or a xenon lamp. The exposure may also be performed by irradiating an h-line, excimer laser, X-ray or electron beam.

After the above exposure, the support film is peeled, followed by development to selectively remove an unexposed area of the photosensitive resin layer, whereby a pattern (for example, lens shape) is formed with the remaining photosensitive resin layer at the exposed area.

After the development, the molded product may be further cured by heating at about 60 to 250° C. or exposing at about 0.2 to 10 mJ/cm² if necessary.

Examples of the method for enhancing the optical stability of the three-dimensional micro-molded product having optical transparency according to the present invention are described with reference to drawings and figures in detail below. This invention is not limited to these Examples.

### EXAMPLES

### Example

A micro lens was made by using a photosensitive resin laminate constituted with a cover film, a photosensitive resin composition layer, and a protective film. Components of the photosensitive resin composition were benzyl methacrylate, methacrylic acid, an alkyl monomer having the average number of functional groups of 2 to 6, a bisphenol A monomer having the average number of functional groups of 2 to 6, a methoxy silane coupling agent, EAB-F, DETX-S (2,4-diethylthioxanthone), B-CIM, and EPA (isopropanol).

The benzyl methacrylate and the methacrylic acid are polymer components for attaining transparency as the micro lens. In addition, the alkyl monomer having the average number of functional groups of 2 to 6 and the bisphenol A monomer having the average number of functional groups of 2 to 6 are monomer components for increasing hardness as a permanent film in a suitable degree for a micro lens. In addition, the methoxy silane coupling agent is a component for improving adhesion to a glass substrate when the photosensitive resin composition layer is transferred to a glass substrate. In addition, the EAB-F and the DETX-S are a polymerization initiator of a radical polymerization system in response to an exposure wavelength of 405 nm (mercurial h-line), and the BCIM is a sensitizer. In addition, the EPA is a solvent. The component ratios of these photosensitive resin compositions are shown below.

### Components of Photosensitive Resin Composition

Copolymer (average molecular weight of 80,000 50% by mass of a MEK solution) at mass ratio 80:20 of benzyl methacrylate: methacrylic acid: 100 parts by mass (in terms of solid content) Dipentaerythritol hexaacrylate (compound (B-1) having a polymerizable tetra- or higher-functional ethylenic unsaturated group in one molecule): 60 parts by mass, NK-ester BPE-100 (the compound (B-2) having a bisphenol skeleton manufactured by Shin-Nakamura Chemical Co., Ltd.): 20 parts by mass, EAB-F (4,4′-bis(diethylamino) benzophenone manufactured by Hodogaya Chemical Co., Ltd.): 0.6 parts by mass, and B-CIM (2-(o-chlorophenyl)-4,5-diphenylimidazolyl dimer manufactured by Hodogaya Chemical Co., Ltd.): 10 parts by mass.

The photosensitive resin composition was applied on a cover film respectively so that the thickness after the drying was 25 μm (transparent polyester film: thickness of 20 μm), A protective film was attached thereon to obtain a photosensitive dry film.

The protective films were peeled off from the photosensitive dry film to expose the photosensitive resin composition layers, and then the exposed surfaces were adhered on a glass substrate. After the photosensitive resin composition layer was placed on the glass substrate in this way, a light mask on which a pattern to actualize a micro lens formed was overlapped on a surface transparent cover film.

The mask having a pattern formed (transmission light volume was varied in equal ratio continually) for actualizing an elliptical micro lens in the glass substrate side was overlapped thereon, and then photoirradiation was conducted at a wavelength of 405 nm. Exposure intensity was 50 mJ/cm² sec at the transparent substrate surface, and illumination intensity was 13 kw/cm² at this time.

After exposure, a light mask was peeled off, the photosensitive resin composition layer and the cover film were peeled off the glass substrate while the photosensitive resin composition layer was unified with the cover film, and then immersed in 1% of an aqueous potassium carbonate (K₂CO₃) solution adjusted at 30° C. for 240 seconds, whereby a non-cured part of the photosensitive resin composition layer was dissolved to be removed. After development treatment with this potassium carbonate water solution, the photosensitive resin composition layer as well as the cover film were washed for 60 seconds with pure water. Then, two ways of heating treatment were conducted at 130° C. for one hour and then 150° C. for one hour to enhance degree of curing of the photosensitive resin composition layer to have the pattern.

To evaluate optical stability of the micro lens made of a resin obtained as previously mentioned. This micro lens was left to stand under a high-temperature and humidity environment at 60° C., 90 RH % for 100 hours.

The surface of each lens of the microlens array after the high-temperature and humidity load was observed with a scanning microscope along a lens curved surface. As a result, as shown in Table 1, it was confirmed that no precipitation of the crystalline substance existed on the lens surface in both cases of two ways of the heating after development. Thus, this Example revealed that the micro lens subjected to the method for optical stabilization of the present invention was in the state with significantly favorable optical stability with time. In Table 1, evaluations are shown which were made at representative observation positions, having a lens thickness of 25 μm, 19 μm, 9 μm, and 3 μm. In addition, in Table 1, “N” shows that no precipitation of the crystalline substance found, while “Y” shows that precipitation of the crystalline was found.

### Comparative Examples 1, 2, and 3

A micro lens was made in the same way as Example except that 1.0% of an aqueous sodium carbonate solution conventionally used as a developing solution (Comparative Example 1), 1.0% of an aqueous m-silicic acid solution (Comparative Example 2), and 0.2% of TMAH (Comparative Example 3). The developing time was 270 seconds in Comparative Example 1, 180 seconds in Comparative Example 2, and 150 seconds Comparative Example 2.

After each micro lens obtained respectively in Comparative Examples, was set under high-temperature and humidity load in the same way as Example, a lens surface was observed with a scanning microscope. The results are shown in Table 1.

TABLE 1

| | Constant temperature and | | | | | | | | | | |
|---|---|---|---|---|---|---|---|---|---|---|---|
| | humidity (60° C. -90 RH %) | | | | | | | | | | |
| | 100 hours | | | | | | | | | Concentration | |
| | Baking condition | 130° C. 1 hour | | | | 150° C. 1 hour | | | | of developing | Developing |
| | Film thickness (μm) | 25 | 19 | 9 | 3 | 25 | 19 | 9 | 3 | solution (%) | time (sec) |
| Example | Existence of | N | N | N | N | N | N | N | N | 1.0 | 270 |
| | crystal- | | | | | | | | | | |
| | line solid | | | | | | | | | | |
| Comparative | | N | N | N | N | Y | Y | Y | N | 1.0 | 180 |
| Example 1 | | | | | | | | | | | |
| Comparative | | Y | Y | Y | Y | Y | Y | Y | N | 1.0 | 240 |
| Example 2 | | | | | | | | | | | |
| Comparative | | N | N | N | Y | Y | Y | Y | Y | 0.2 | 150 |
| Example 3 | | | | | | | | | | | |

In order to obtain a molded product having comparatively high hardness as a permanent film such as micro lens, it is desired that heating be conducted at a temperature as high as possible after exposure (development). Even in Comparative Examples 1 and 3 in which no precipitation of the crystalline substance was confirmed in a sample heated after exposure at 130° C., precipitation of the crystalline substance was confirmed over the almost entire face of the lens with the samples heated after exposure at 150° C. Thus, it was verified that the micro lenses of Comparative Examples 1, 2, and 3 had insufficient optical stability with time.

### INDUSTRIAL APPLICABILITY

The method for enhancing the optical stability of the three-dimensional micro-molded product having optical transparency according to the present invention can provide optical stability so as not to cause precipitation of crystalline substance which results in haze in the molded product even when a three-dimensional micro-molded product is used under a high-temperature and humidity environment deviated from a normal use environment. Thus, the present invention can enhance reliability of fine optical elements such as micro lenses built in optical components, and the life time can be greatly improved.

1. A method for enhancing the optical stability of the three-dimensional micro-molded product having optical transparency, wherein the three-dimensional micro-molded product is obtained by irradiating actinic rays from the transparent substrate side to a formed layer including a photosensitive resin composition provided on a transparent substrate so that light volume varies along the planer direction of the transparent substrate and dissolving and removing a non-cured part of the formed layer after irradiation in developing solution, and wherein potassium carbonate solution is used as the developing solution.

2. The method according to claim 1, wherein the optical stability is maintained after high-temperature and humidity load.

3. The method according to claim 2, wherein the high-temperature and humidity load is to maintain under an environment at 60° C. and 90 RH % for at least 100 hours.

4. The method according to claim 1, wherein the optical stability is maintenance of the optical transparency.

5. The method according to claim 4, wherein the maintenance of the optical transparency is that there is no precipitation of the crystalline substance in the molded product even after the high-temperature and humidity load.

6. The method according to claim 1, wherein the formed layer is obtained by transferring a photosensitive resin composition layer of a photosensitive dry film constituted with at least a cover film and the photosensitive resin composition layer formed thereon on the transparent substrate.
